(19) United States
(12) Patent Application Publication
(10) Pub. No.: US 2025/0155294 A1
(43) Pub. Date: May 15, 2025

(54) MEASUREMENT METHOD FOR ESTIMATING TEMPERATURE OF POWER SEMICONDUCTOR MODULE

(71) Applicant: MITSUBISHI ELECTRIC CORPORATION, Tokyo (JP)

(72) Inventors: Julio BRANDELERO, RENNES Cedex 7 (FR); Briac BAUDAIS, RENNES Cedex 7 (FR)

(73) Assignee: MITSUBISHI ELECTRIC CORPORATION, Tokyo (JP)

(21) Appl. No.: 18/839,532

(22) PCT Filed: Jul. 22, 2022
(86) PCT No.: PCT/JP2022/029216

§ 371 Date: Aug. 19, 2024

(30) Foreign Application Priority Data
Mar. 23, 2022 (EP) 22305348.9

(51) Int. Cl. G01K 7/01; G01K 3/04; G01R 19/00

(52) U.S. Cl. CPC G01K 7/01; G01K 3/04; G01R 19/0038

(57) ABSTRACT

A measurement method for estimating temperatures of a MOS/MIS power semiconductor module comprising:
in a reference state
a. injecting a positive current Ig,ref to the gate, an initial voltage V0,ref of the gate-emitter/source, being superior to a flatband voltage Vfb,
b. measuring the voltage Vig,ref(t) across the current source,
c. stop the current injection Ig,ref when the voltage becomes inferior to the flatband voltage Vfb,
in an operational state
d. injecting a positive current Ig,op to the gate, an initial voltage V0,op of gate-emitter/source, being superior to a flatband voltage Vfb,
e. measuring the voltage Vig,op(t) across the current source,
f. stop the current injection Ig,op when the voltage becomes inferior to the flatband voltage Vfb,
then
g. comparing the measured voltages Vig,ref(t) and Vig,op(t),
h. deducing, from the comparison, a temperature dispersion Tj,dev across the module.

### TECHNICAL FIELD

This disclosure pertains to the field of power semiconductor monitoring.

### BACKGROUND ART

It is known to monitor temperature in power semiconductor Metal-Oxide-Semiconductor type (MOS) or paralleled connected power semiconductor MOS types, especially in power semiconductors devices/modules, like multichip power modules, for protection, condition and health monitoring. Generally, the free surface of a die is very small. To fix a sensor on it is difficult, and even impossible in some cases. Theoretically, using individual gate access of the power dies to measure the individual gate resistances, which are thermal sensitive parameter, would be obvious. But the number of external connections is high, and the acquisition system is complex. To do it in laboratory conditions is very difficult. In real, industrial and operational situations, to use individual PN junction sensors is not realistic.

In addition, sensors have to be integrated inside the power module packaging which means that the presence of sensors have to be initially planned during the conception of the module and to retrofit to the existing power modules is impossible.

Many Temperature Sensitive Electrical Parameters (TSEP) based methods and in-chip sensors for on-line junction temperature estimation on power semiconductor are known. The followings are examples of measures and operations used to deduce a TSEP:
the gate voltage plateau sensing during turn-on
the turn-off delay time (t_{dOff}),
the turn-on delay time (t_{dOn}),
the time duration of Miller plateau,
the quasi threshold voltage via the auxiliary emitter (source) and the power emitter (source),
the peak of the transient gate current during turn-on,
applying a sinusoidal voltage on the gate-emitter and instantly measuring the voltage drop across the external gate resistor,
injecting a DC current into the gate path of the power die and measuring the voltage across the gate emitter.

For each one of these known methods, the necessary calibration of the TSEP is only possible in a homogeneous temperature. Although, temperature inhomogeneities during the normal operation will lead to erroneous junction temperature estimations because only a single TSEP is available for the paralleled dies. The accuracy of the TSEP depends on the average, maximum or minimum temperatures. As explained in C. Chen, V. Pickert, B. Ji, C. Ji, A. Knoll and C. Ng, “Comparison of TSEP Performances Operating at Homogeneous and Inhomogeneous Temperature Distribution in Multichip IGBT Power Modules” IEEE Journal of Emerging and Selected Topics in Power Electronics, the Collector-Emitter Voltage (V_{ce}) is one of the TSEP with the best accuracy for the average temperature while other TSEP as the dV_{CE}/dt fails completely in estimating the junction temperature. The main reason is that the hottest die has the highest Miller capacitance and consequently would have the slowest rising of V_{CE}. Furthermore, the Miller plateau difference estimates the average temperature. In M. Hoeer, F. Filsecker, M. Wagner and S. Bernet, “Application issues of an online temperature estimation method in a high-power 4.5 kV IGBT module based on the gate-emitter threshold voltage”, 2016, 18th European Conference on Power Electronics and Applica, the quasi-threshold method has been investigated for dies in parallel. The method shows that the lowest threshold Voltage (Vₜₕ) is measured, which may correspond to the maximum junction temperature (Tⱼ) if all the dies have the same Vₜₕ which it's not the case (an error up to 25K for 50K increase has been measured). Moreover, as the performance of the dies are related to the temperature, a temperature imbalance will change the TSEP sensitivity and linearity.

Losses and thermal models can be used to compensate the estimated virtual junction temperature to the maximum or to temperature difference between the dies. Nonetheless, these methods require complex calibration system of the loss and thermal models and will lose accuracy during the lifetime of the power modules in case of solder layer degradation, or generally if differences appear between operational conditions during the lifetime of the module and the initial model.

### SUMMARY OF INVENTION

This disclosure improves the situation.

It is proposed a measurement method for estimating temperatures of a power semiconductor module comprising a single Metal-Oxide-Semiconductor, a single Metal-insulator-Semiconductor or a set of Metal-Oxide-Semiconductors or Metal-insulator-Semiconductors paralleled connected. The method comprises:
at least one first series of operations, during which the module is in a reference state, including
a. injecting a positive current I_{g,ref} from the emitter/source to the gate of said module, an initial voltage V_{0,ref} of the module, gate-emitter/source, being superior to a flatband voltage V_{fb},
b. measuring the voltage V_{ig,ref}(t) across the current source,
c. stop the current injection I_{g,ref} when the voltage of the module becomes inferior to the flatband voltage V_{fb},
at least one second series of operations, during which the module is in a operational state, including
d. injecting a positive current I_{g,op} from the emitter/source to the gate of said module, an initial voltage V_{0,op} of the module, gate-emitter/source, being superior to a flatband voltage V_{fb},
e. measuring the voltage V_{ig,op}(t) across the current source,
f. stop the current injection I_{g,op} when the voltage of the module becomes inferior to the flatband voltage V_{fb},
then,
at least one third series of operations including
g. comparing the voltages V_{ig,ref}(t) and V_{ig,op}(t) measured respectively during one said first series and one said second series,
h. deducing, from the comparison, a temperature dispersion T_{j,dev} across the module.

In another aspect, it is proposed a power semiconductor module comprising a single Metal-Oxide-Semiconductor, a single Metal-insulator-Semiconductor or a set of Metal-Oxide-Semiconductors or Metal-insulator-Semiconductors paralleled connected, and being arranged to implement the method described here.

In another aspect, it is proposed a computer software comprising instructions to implement the method as defined here when the software is executed by a processor. In another aspect, it is proposed a computer-readable non-transient recording medium on which a software is registered to implement the method as defined here when the software is executed by a processor.

The following features, can be optionally implemented, separately or in combination one with the others.

Each of said at least one first series and said at least one second series further comprises:
i. acquiring absolute average temperatures T_{av,ref} and T_{av,op} of the module, wherein said second series is repeatedly executed until that the difference between the absolute average temperatures T_{av,ref} and T_{av,op} acquired during said at least one first series and during said second series is equal or inferior to a predetermined value ΔTₗᵢₘ.

A plurality of said first series is executed at different absolute average temperatures T_{av,ref,n},

wherein said first series are executed during states different from an operational state of the module.

A plurality of said first series is executed at different absolute average temperatures T_{av,ref,n},

wherein each said first series is executed during a reference and operational state of the module, and before reaching a predefined operating age limit in operational operation of said module.

Said third series further comprises, before comparison:

g′. adjusting, in time and in offset, the measured voltage V_{ig,op}(t) during said at least one second series with respect to the waveform of the measured voltage V_{ig,ref}(t) during said at least one first series.

Each said at least one first series is executed when the power transferred by the module is inferior to a predefined limit strictly inferior to the nominal maximum load of the module.

Other features, details and advantages will be shown in the following detailed description and on the figures.

### BRIEF DESCRIPTION OF DRAWINGS

FIG. 1 is a thermal view of a semiconductor device at the beginning of its life use (a new one).

FIG. 2 is a thermal view of a semiconductor device at during its life use (a deteriorated one).

FIG. 3 is a thermal view of a semiconductor module including six parallel connected semiconductor devices.

FIG. 4 is the equivalent circuit of the module shown on FIG. 3.

FIG. 5 is circuitry according to an embodiment.

FIG. 6 is a graphic view of some data obtained during an embodiment.

FIG. 7 is a graphic view of some data obtained during an embodiment.

FIG. 8 is a flowchart executed during an embodiment.

FIG. 9 is a flowchart of an algorithm executed during an embodiment.

FIG. 10 is a graphic view of voltages in function of time.

FIG. 11 is the same graphic view as FIG. 10 after an adjustment of values/curves.

FIG. 12 is a graphic view of voltages deviation in function of temperatures deviations.

FIG. 13 is a graphic view of a gate-emitter voltage in function of time.

### DESCRIPTION OF EMBODIMENTS

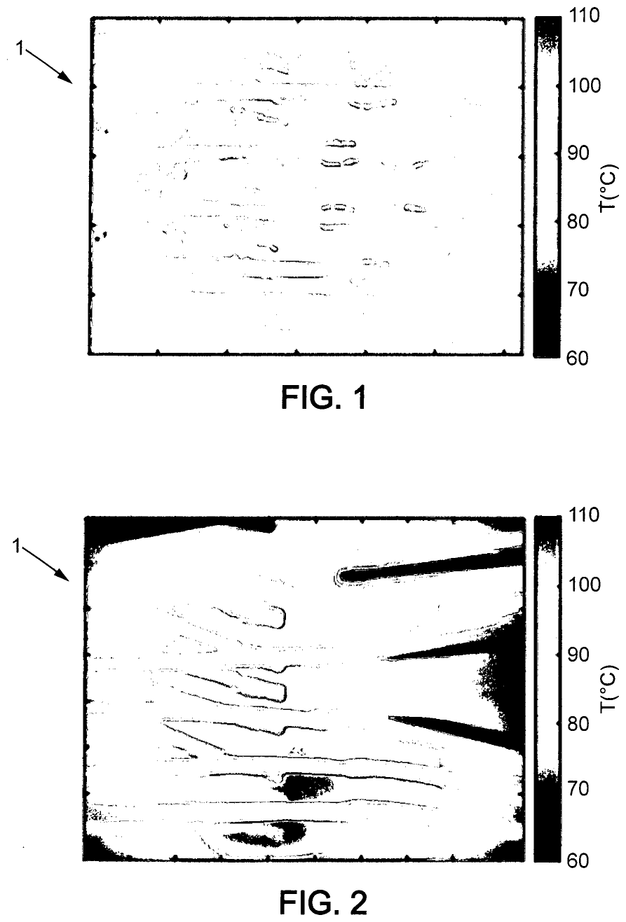

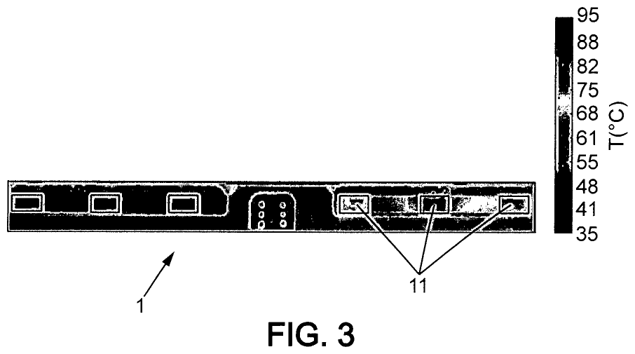

It is now referred to FIGS. 1 to 4. FIG. 1 and FIG. 2 are thermal pictures of two power semiconductor modules 1 having the same architecture but taken at two different steps of their operating life. Module 1 of FIG. 1 is new and in operating conditions from a short time while module 1 shown on FIG. 2 is deteriorated by operating conditions from a long time. Such pictures clearly show that important heterogeneity of temperatures in a single device (here a die) can appear during lifetime of a module 1. FIG. 3 and FIG. 4 show another power semiconductor module 1 comprising six parallel connected semiconductor elements 11 (dies). Such pictures clearly show that important heterogeneity of temperatures can appear between devices (here dies) of the same module 1 during lifetime of the module 1.

To monitor such temperatures in laboratory conditions, some of measurements method can be used. Here, a measurement method for estimating temperatures of a power semiconductor module 1 is proposed that can be used in operational conditions, typically not on a test bench but when the module is integrated and interconnected in its operational and application environment.

In the following, power semiconductor modules are assembly comprising a single Metal-Oxide-Semiconductor (MOS) transistor, a single Metal-insulator-Semiconductor (MIS) or a set of MOS/MIS transistor paralleled connected. Herein, the transistor are MOSFETS (“Metal Oxide Semiconductor Field Effect Transistor”) but IGBT (“Insulated Gate Bipolar Transistor”) can also be used. When a plurality of MOS/MIS are paralleled connected, there is a common gate G, a common source S and a common drain D. For this reason, it is referred to a single gate, a single source and a single drain in the following without distinction of embodiments with a single one or a plurality of MOS transistor elements. The word “power” is used in its general meaning of the technical field of energy conversion (power electronics).

The method comprises:
at least one first series I of operations, during which the module 1 is in a reference state,
at least one second series II of operations, during which the module 1 is in an operational state, and
at least one third series III of operations.

The reference state corresponds to a state wherein the MOS is/are in a known state: the temperature heterogeneity in the module 1 is known to be inferior to predetermined maximum ΔT_{ref}, preferably as low as possible. For example, all the dies are heated to the same temperature and no power is dissipated on the dies. Such a reference state enables to obtain reference values for the module 1.

In the following examples, such a reference state is controlled. But, in various embodiments, the reference state can correspond to a specific period of operation of the module 1 during which the MOS element(s) 11 is/are in a known stable state, for example an off state.

In the following examples, the module 1 comprises (or is connected to) a control circuitry 2, including:
a voltage source 21 (V_{drive}) arranged to pre-set the voltages of the MOS element(s) 11 of the module 1 at a value V_{0,ref} superior to its flatband voltage V_{fb}; such a voltage source 21 can be not specifically dedicated to the method described here. In other words, the voltage source 21 can be a usual component of the module which is also active during classical operations of the module;
a current source 22 (I_{g}), for example from 1 mA to 100 mA;
a control unit 23 arranged to start and stop the current source 22, here via a control line CTRL2;
voltage measurements means
a calculation unit 24 arranged to implement the third series III of operations.

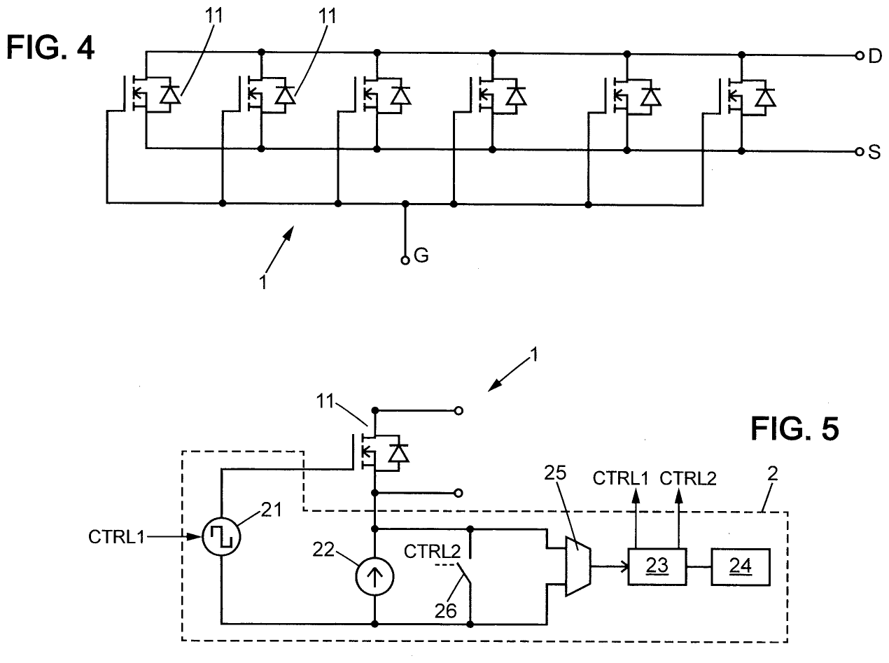

FIG. 5 shows an example of implementation a control circuitry 2 and a module 1. For simplification, a single MOS element 11 is represented on FIG. 5. But the single MOS element 11 could be replaced by a plurality of MOS elements 11 paralleled connected. In the example, the control circuitry 2 further comprises an Analog-to-Digital Converter (ADC) 25 associated to the control unit 23 and a switch 26 arranged to control the feeding of the MOS element(s) 11 by the current source 22 and controlled by the control unit 23, here via a control line CTRL2.

An electrical isolation between the switch 26 and the ADC 25, and/or between the ADC 25 and control unit 23, and/or between signal lines CTRL1 and CTRL2 can also be provided.

The first series I of operations is, for example, executed by the control circuitry 2, and especially driven by its control unit 23. The control unit 23 can includes a Central Processing Unit (CPU) and/or logic ports and/or Field-Programmable Gate Array (FPGA).

The first series I of operations includes:
a. injecting a positive current I_{g,ref} from the emitter/source to the gate of said module 1, an initial voltage V_{0,ref} of the module 1, gate-emitter/source, being superior to a flatband voltage V_{fb},
b. measuring the voltage V_{ig,ref}(t) across the current source,
c. stop the current injection I_{g,ref} when the voltage of the module 1 becomes inferior to the flatband voltage V_{fb}.

In an embodiment wherein the first series I of operations is executed by the control circuitry 2, measures of the voltage V_{ig,ref}(t) across the current source are made by the voltage measurement means. Before to stop the current injection I_{g,ref}, conditions can be monitored and detected by the control unit 23 through the ADC 25 of the control circuitry 2, or be imposed in a constant time, for example 2 μs. When the conditions are fulfilled (the voltage of the module 1 becomes inferior to the flatband voltage V_{fb}), the control unit 23 send a control signal to the switch 26 of the control circuitry 2 to close it such that the current source 22 stops feeding the MOS element(s) 11.

The first series I of operations is executed at a known average temperature of the module 1, for example the maximum nominal average temperature of the module 1 during its operational life. This enables to obtain measures for the said average temperature. In the following examples, the average temperature is 135° C. The said temperature is adapted in function of each architecture and context of operations (applications and designs) of the modules 1. Optionally, the first series of operations can be repeated at various known average temperatures of the module 1 in order to obtain a plurality of sets of measurements, each one being related to a known average temperature.

Then (or before), the second series II of operations is executed. The second series II of operations is substantially similar to the first one I but is made during an operational state wherein the MOS is/are in an unknown state, or at least for which the temperature heterogeneity in the module 1 is looking for. Preferably, the average temperature of the module 1 is known.

The second series II of operations includes:
d. injecting a positive current I_{g,op} (typically equal to the injected current I_{g,ref} of the previous first series I) from the emitter/source to the gate of said module 1, an initial voltage V_{0,op} of the module, gate-emitter/source, being superior to a flatband voltage V_{fb},
e. measuring the voltage V_{ig,op}(t) across the current source,
f. stop the current injection I_{g,op} when the voltage of the module (1) becomes inferior to the flatband voltage V_{fb}.

In an embodiment wherein the second series II of operations is executed by the control circuitry 2, measures of the voltage V_{ig,op}(t) across the current source are made by the voltage measurement means. Before to stop the current injection I_{g,op}, conditions can be monitored and detected by the control unit 23 through the ADC 25 of the control circuitry 2, or be imposed in a constant time, for example 2 μs. When the conditions are fulfilled (the voltage of the module 1 becomes inferior to the flatband voltage V_{fb}), the control unit 23 send a control signal to the switch 26 of the control circuitry 2 to close it such that the current source 22 stops feeding the MOS element(s) 11.

During the second series II of operations, during the operation of the MOS element(s), and especially at a maximum operating point, the junction temperature can differ in a unique power semiconductor surface or on the several dies in parallel. Thus, the measured voltage V_{ig,op}(t) across the current source differs from the measures obtained during the first series I of operations. In other words, the waveforms in function of the time t are not formed equally.

The operation of the module 1 can be driven by a Central Processing Unit (CPU), preferably the same as during the first series I of operations, like the control unit 23 of the control circuitry 2.

Then, the third series III of operations includes:
g. comparing the voltages V_{ig,ref}(t) and V_{ig,op}(t) measured respectively during one said first series I and one said second series II,
h. deducing, from the comparison, a temperature dispersion T_{j,dev} across the module 1.

The third series III of operation is made by a processing unit, for example the calculation unit 24 of the control circuitry 2. In the examples described here, the calculation unit 24 is considered distinctly from the control unit 23 (see FIG. 5) to better understand their respective functions. In some embodiments, the calculation unit 24 can be a part of (integrated to) the control unit. 23 and being structurally the same component, especially in the embodiments wherein an isolation is provided between the control unit 23 and the ADC 25.

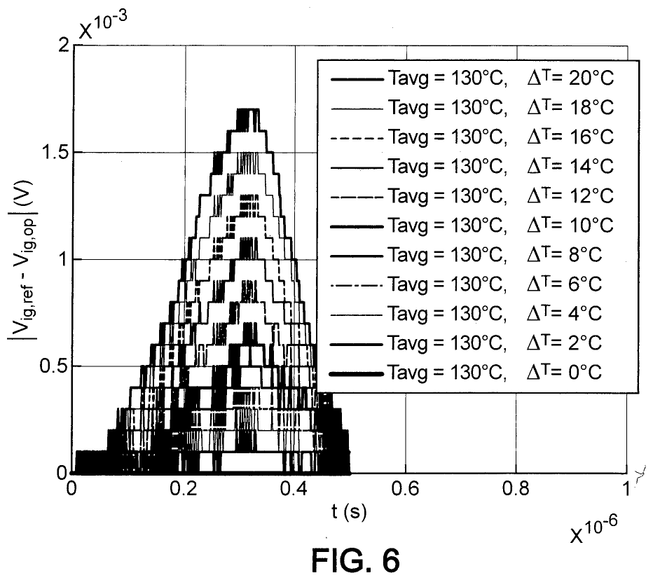

The comparison of the voltages V_{ig,ref}(t) and V_{ig,op}(t) is preferably made for similar or close average temperatures of the module 1. The aim is to identify the variations on the acquired voltage given the temperature gradient among the power semiconductor elements 11 or within a unique power semiconductor element of the module 1. FIG. 6 shows an example of such a comparison. In the example of FIG. 6, the graphic represents the absolute difference of the voltages (|V_{ig,ref}(t)−V_{ig,op}(t)|) obtained during the first series I and the second series II in function of the time (t). In the said example, all the curves corresponding to an average temperature of the module 1 of 130° C. and each curve corresponds to a temperature gradient (here from 0 to 20° C. by step of 2° C.) among the power semiconductor elements 11.

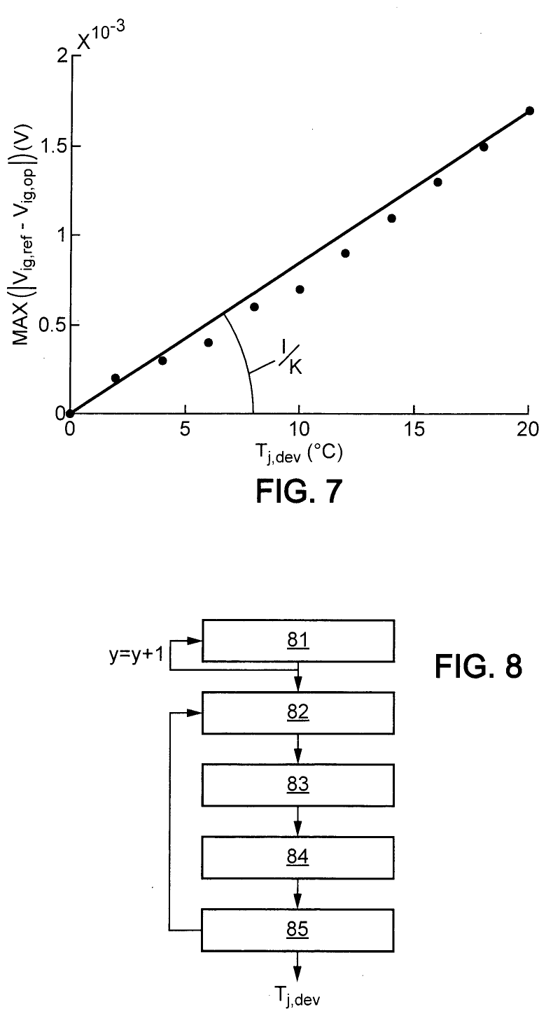

In an example, the deduction of the junction temperature dispersion T_{j,dev} is based only on the maximum values of the absolute difference between the voltages V_{ig,ref}(t) and V_{ig,op}(t), multiplied by a predetermined factor K which is calculated from a simulation of the flatband behavior, e.g. K=11 800° C./V. This is represented in FIG. 7.

The graphical representation of the comparison of FIG. 7 is only an example to help the reader to understand but the method is not limited to any specific manner to execute such a comparison: the comparison can be made only with the numerical data measured and/or with a graphical analysis.

The temperature dispersion in a semiconductor region or the temperature dispersion of an array of semiconductors elements 11 connected in parallel can then be estimated using a unique indicator (voltage across the current source). Any individual access isn't necessary. Furthermore, the estimation is made for the most critic operating situation.

The comparison of the voltages V_{ig,ref}(t) and V_{ig,op}(t) is preferably made for similar or close average temperatures of the module 1. In order to ensure that, each of said at least one first series I and said at least one second series II further comprises:
i. acquiring an absolute average temperature T_{av,ref} and T_{av,op} of the module 1.

The second series II is repeatedly executed until that the difference between the absolute average temperatures T_{av,ref} and T_{av,op} acquired during said at least one first series I and during said second series II is equal or inferior to a predetermined value ΔTₗᵢₘ.

For example, the average temperature can be determined using TSEP-based method known by itself, for example in function of the internal gate resistance. Such methods are explained in C. Chen, V. Pickert, B. Ji, C. Ji, A. Knoll and C. Ng, “Comparison of TSEP Performances Operating at Homogeneous and Inhomogeneous Temperature Distribution in Multichip IGBT Power Modules” IEEE Journal of Emerging and Selected Topics in Power Electronics. The measurement of the voltage V_{ig,ref}(t) or V_{ig,op}(t) at the initial instants, t1, after the current injection, e.g. 500 ns after the current injection, is representative of the average junction temperature. In the fact, the initial voltage just after the current injection is representative of the internal gate resistance R_{g,in}. It's known that this method represents the average junction temperature. The V_{ig,ref}(t1) or V_{ig,op}(t1) can be correlated to the absolute junction temperature during the first and second series I and II.

Advantageous, the temperature heterogeneity is calculated without the acknowledgment of the operating point of the power semiconductors. Furthermore, by using the R_{g,in} TSEP-based method, a unique circuit is enough to measure the absolute average and the dispersion of the junction temperature in a unique power semiconductor or in paralleled power semiconductor elements 11.

In some embodiments, the first series I of operations to obtain V_{ig,ref}(t) is made when the module 1 is in a reference state and not in an operational situation (typically in laboratory, product calibration phase or maintenance conditions). The first series I can be repeatedly made (N times) at various temperatures to obtain measures of V_{ig,ref}(t) under various temperatures. In such conditions, the temperatures do not depend on the operational conditions and can be chosen/driven. For example, an external heating element can be disposed in the vicinity of the module 1, like a heating plate. In another example, the temperature of a heat sink where power dies are attached can be chosen/driven.

When the first series I of operations is made in a non-operational situation, then the temperature dispersion can be estimated for any average temperature during the power module usage with a good accuracy.

This is shown in FIG. 8:
In a first loop 81, V_{ig,ref} is measured for a first absolute average temperatures T_{av,ref,y} in a situation where the temperature is known homogenous in the module 1 (the module 1 being off-line), which means the same at each junction of the module 1 (T_{av,ref,y}=T_{j1,dev}=T_{j2,dev}= . . . =T_{jN,dev}). Then, the loop is reiterated for another absolute average temperatures T_{av,ref,y}+1 for each absolute average temperatures T_{av,ref,y}+N;
Then, in a sub-step 82, the average temperature T_{av,op} is determined, for example using TSEP-based method, like in function of the internal gate resistance;
Then executing the measuring of the voltage V_{ig,op}(t) across the module 1 (operation e, corresponding to 83 in FIG. 8;
Then executing the comparison (operation g, corresponding to 84 in FIG. 8), preferably with the reference voltage V_{ig,ref} obtained with absolute average temperatures T_{av,ref},y closest to the determined average temperature T_{av,op};
Then deducing (operation h, corresponding to 85 in FIG. 8), a temperature dispersion T_{j,dev} across the module 1 as the minimum of the product of the factor K and the absolute difference between the two voltages T_{j,dev}=K·max (|V_{ig,op}−V_{ig,ref}|).

In some other embodiments, the first series I of operations to obtain V_{ig,ref}(t) is made when the module 1 is in a reference state during an operational situation, in an early stage of its usage, for example before reaching a predefined operating age of the module 1. Only as examples, the predefined operating age can be set as a percentage (strictly inferior to 100%, for example 5%, 10% or 20%) of a target/nominal lifetime limit, or it can be set as a number of hours, like 1 000, 2 000 or 10 000 hours depending on the module, operational conditions and/or an aimed safety level. The first series I can be repeatedly made (N times) at various temperatures to obtain measures of V_{ig,ref} (t) under various temperatures. In such conditions, a set of measures for various known temperatures can be obtained.

Here, we define the “early stage” as a number of hours in operation. In such a case, a counter can be installed in the control unit 23 that enables to define the limit in time in which the first series is/are performed. In our example, the number is set as 100 hours. Within this time, no degradation will occur on the power semiconductor packaging (the module 1) and the temperatures of the power semiconductor element(s) are considered homogenous by the design. A person skilled in the art could adapt such a limit in view of the context.

When the first series I of operations is made in an early stage of operational situation, the temperature heterogeneity evolution during the lifetime in case of the deterioration of the power semiconductor elements can be retrieved. Furthermore, any commissioning phase is necessary before the usage of power semiconductor. Consequently, the V_{ig,ref}(t) used as reference is generated during the field application reducing the manufacturing complexity.

In some embodiments, said third series III further comprises, before comparison:
g′. adjusting, in time and in offset, the measured voltage V_{ig,op}(t) during the at least one second series II with respect to the waveform of the measured voltage V_{ig,ref}(t) during the at least one first series I.

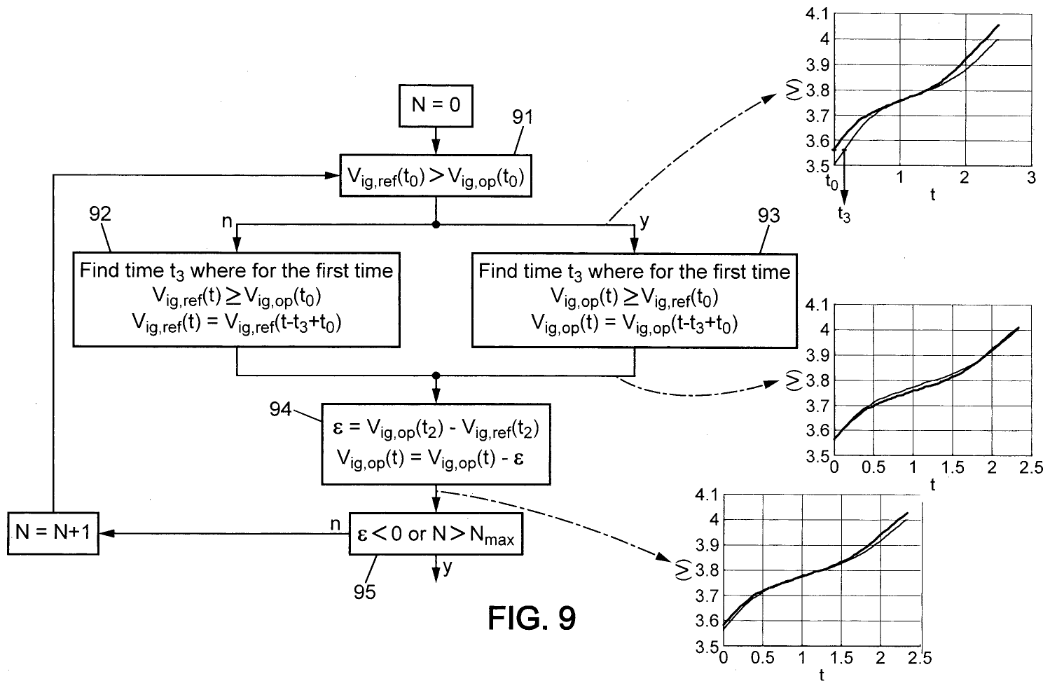

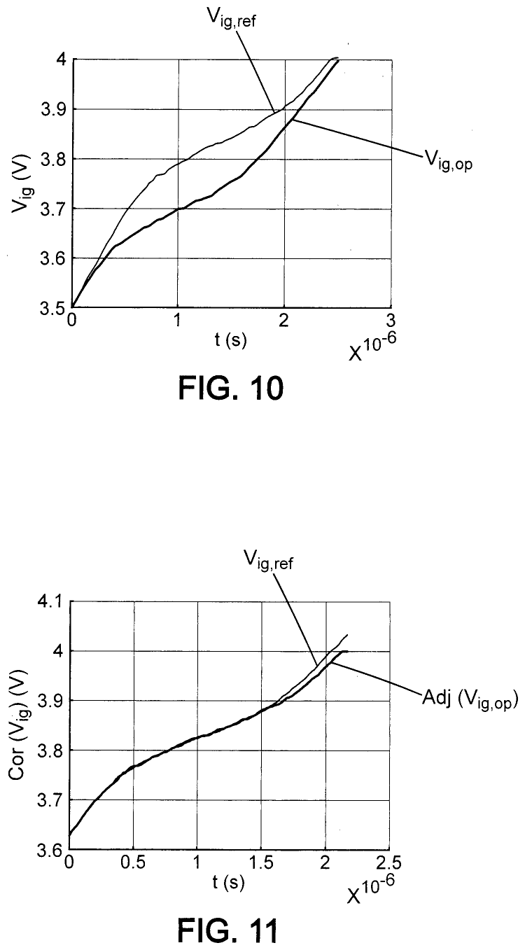

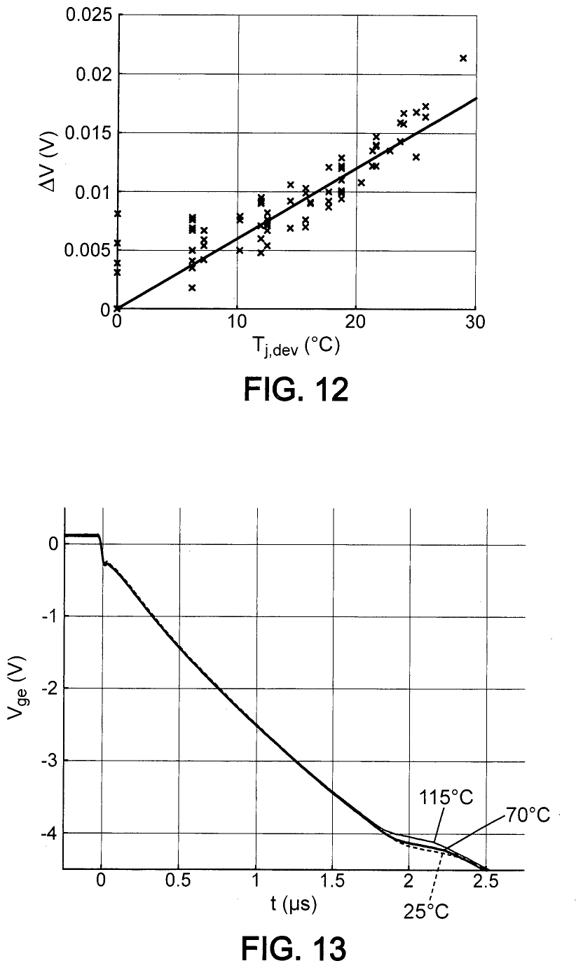

Such operation can be explained by the principle that the flatband voltage changes in time and voltage amplitude dependently on the drain-source voltage and/or average temperature. However it does not impact on the shape of the waveform. An example of an algorithm to execute the offset and time shift is represented on FIG. 9. The algorithm searches the instant, t3, where the waveforms have the same amplitude for the first time. In this purpose, the algorithm first compares the initial voltages of V_{ig,op}(t₀), V_{ig,ref}(t₀) at step 91. Thus, it moves to steps 92 or 93, where it searches for the voltage where Vx(t₀) is equal to Vy(t₃) (Vx being the V_{ig,op} and Vy being the V_{ig,op} at step 92 and the opposite in step 93). Therefore, the time delay t₃ can be compensated at the smaller amplitude waveform based on the biggest Vx(t₀), which guarantee that V_{ig,op}(t₀)=V_{ig,ref}(t₀). Then the algorithm moves to step 94, where the amplitude offset is removed. The offset is defined as being the voltage difference at a time t₂ that is placed in the middle of the plateau of the V_{ig,ref}(t) waveform, for example at 1 μs. If this offset is smaller enough, example 4 mV, then the algorithm has converged the waveforms, otherwise, the algorithm returns to step 91. The algorithm can be stopped after a number of interactions. According to experiments, five interactions are enough. FIG. 10 and FIG. 11 are graphical representations of the measured voltage V_{ig,op}(t) respectively before and after the adjusting operation, the after being referenced as a function “Adj(V_{ig,op}(t))”. In these figures the difference between V_{ig,op}(t) and V_{ig,op}(t) are obtained at different bus voltages and average junction temperatures, with no inhomogeneity present. As demonstrated, this adjustment enables to remove the offset and delays introduced by external factors as the average temperatures or drain-source voltages. Only the temperature inhomogeneity changes the shape of the waveform, thus the difference between “Adj(V_{ig,op}(t))” and V_{ig,op} (t) will result in the same difference as shown in FIG. 6, where the results are exploited in FIG. 7 by taking the maximum. A resulting variation after the adjustment in function of the standard deviation of the junction temperatures is shown on FIG. 12. In such an example, the temperature gradient can be retrieved with a coefficient K=1 650° C./V.

In some embodiments, a single measurement of V_{ig,ref}(t) is made. An arbitrary average junction temperature is determined. This reduces the time of the calibration after the manufacturing of module.

In some embodiments, each first series I is executed when the power transferred by the module 1 is inferior to a predefined limit strictly inferior to a nominal maximum load of the module 1. Only as examples, the predefined limit can be set as a percentage (strictly inferior to 100%, for example 5%, 10% or 20%) of a target/nominal maximum load. In various embodiments, a limit condition can be set as a maximum allowed power dissipation, like 5%, 10% or 20% of a nominal maximum power dissipation, depending on the module, operational conditions and/or an aimed safety level. A combination of such limits can be implemented. For example, predetermined conditions can be set into a control unit 23 to trigger the voltage V_{ig,ref}(t) acquisition. The following conditions give good results:
the power semiconductor element(s) is/are not switching, and a non-zero drain-source voltage V_{ds}, or a non-zero collector-emitter voltage V_{ce} is present across the power semiconductor element(s); or
a small collector-emitter current Ice or small drain-source current I_{ds} is flowing through the power semiconductor element(s) when a non-zero drain-source or collector-emitter voltage, is present across the power semiconductor element(s) and the last one is switching.

The V_{ce} or V_{ds} can be measured and stored in a table linked to the voltage V_{ig,ref}(t). In such a case, the comparison (operation g) can be made when the V_{ig,ref} obtained is the same, or near, the V_{ce} or V_{ds} values.

Advantageous, the sensitivity of the flatband voltage with the V_{ce} and V_{ds} voltages can be compensated and the deterioration of the flatband, caused by the accumulation of charges on the gate oxide, is also compensated. {Theory}

The flatband voltage V_{fb} represents the voltage applied to the gate when no charge is present in the oxide or at the oxide-semiconductor interface that yields a flat band energy in the semiconductor. The voltage is the difference between the gate metal workfunction and the semiconductor workfunction. The workfunction is the voltage required to extract an electron from the Fermi energy to the vacuum level. This voltage separates the accumulation mode to the depletion mode of a MOS (metal oxide semiconductor) structure. During the accumulation mode, the MOS capacitance C is only related to the oxide capacitance. During the depletion mode, the MOS equivalent capacitance is a series connection of the oxide capacitance and the variable capacitance of the depletion layer C_{eq}.

In operational context, the power semiconductors are classically operated by a main controlled that alternates the on and off state modes by applying a positive voltage V_{ge} (e.g. 15V) and a negative voltage V_{ge} (e.g. −15V) respectively.

Here, the temperature dispersion is measured by considering the change on the gate-emitter voltage behavior when the MOS capacitor is pre-charge to a voltage V_{ge} higher than the MOS flatband voltage (for example around −2V) and a low amplitude current source (for example 1 mA-100 mA) discharges the MOS capacitor until the voltage V_{ge} is inferior to the flatband voltage V_{fb} that can vary between power semiconductor references and its normally comprised in a known range, for example from −10V to −3V. The discharge characteristics can be seen on FIG. 13 on which the flatband signature on the V_{ge} voltage of an IGBT can be seen. The discharge of the MOS capacitor shows a plateau during the flatband voltage which can be readily identified and be dependent on the junction temperature. This specific relation between the flatband voltage V_{fb} and the junction temperature Tⱼ enables to deduce the temperature dispersion T_{j,dev} in function of the voltages dispersions.

In order to determine the flatband voltages V_{fb} of dies (or any semiconductor element), the input impedance of the power semiconductor element can be model by the equivalent capacitor C_{eq}. Thus, using a current source I_{g} is an advantage in this method as the amount of charge Qₜ injected on the gate of the power semiconductor element (see Math. 1) is controlled and proportional to the equivalent capacitor (see Math. 2).

$${Q}_{t} = {I}_{g} \cdot ( t - {t}_{0} ) = {\sum }_{n = 1 … N} ( {Q}_{n} ( t ) - {Q}_{n} ( {t}_{0} ) ) \qquad [ Math . 1 ]$$

$${V}_{ig} = \frac{{Q}_{t}}{{C}_{e q}} with {C}_{e q} = {\sum }_{n = 1 … N} C ( {V}_{fb}^{n} ) \qquad [ Math . 2 ]$$

Qₙ being the charge stored in the n^{th} semiconductor, to being the initial time and t being the current time. As the equivalent capacitor C_{eq} is dependent on the each flatband voltage Vⁿ_{fb}, the measure of the voltage V_{ig} enables to determine the equivalent capacitor factor at each instant of the time t. Using a voltage V_{ig} acquired in a homogeneous temperature and compared to a voltage V_{ig} acquired in an unknown situation enables to determine the variation on the flatband voltage V_{fb}. Thus, methods to explore the variation on V_{ig} is proposed here to extract the flatband inhomogeneities related to the temperature inhomogeneities.

### INDUSTRIAL APPLICABILITY

The technical solutions presented here can be used to deduce junction temperature dispersion (temperature inhomogeneities) of at least one power semiconductor MOS type or paralleled connected power semiconductor MOS types by using flatband voltage measurement methods on the paralleled gate/source-emitter access of the parallel power elements in order to identify the signature of the individual flatband voltages and thus deduce the individual junction temperatures. As the flatband voltage signature is also affected by the operating point of the power semiconductor element(s) (e.g. drain-source/collector-emitter voltage), the individual temperatures are deduced in relative values.

Advantageous, the temperature dispersion in the semiconductor region or the temperature dispersion of an array of semiconductors connected in parallel can be estimated using a unique indicator (voltage across the current source), thus any individual access becomes unnecessary.

This disclosure is not limited to the methods, modules, components and computer softwares described here, which are only examples. The invention encompasses every alternative that a person skilled in the art would envisage when reading this text.

### REFERENCE SIGNS LIST

1: module
2: control circuitry
11: element
21: voltage source
22: current source
23: control unit
24: calculation unit
25: Analog-to-Digital Converter (ADC)
26: switch
81: loop
82: sub-step
83: operation
84: operation
85: operation.

1. A measurement method for estimating temperatures of a power semiconductor module comprising a single Metal-Oxide-Semiconductor, a single Metal-insulator-Semiconductor or a set of Metal-Oxide-Semiconductors or Metal-insulator-Semiconductor paralleled connected, said method comprising:
at least one first series of operations, during which the module is in a reference state, including
a. injecting a positive current I_{g,ref} from the emitter/source to the gate of said module, an initial voltage V_{0,ref} of the module, gate-emitter/source, being superior to a flatband voltage V_{fb},
b. measuring the voltage V_{ig,ref}(t) across the current source,
c. stop the current injection I_{g,ref} when the voltage of the module becomes inferior to the flatband voltage V_{fb},
at least one second series of operations, during which the module is in a operational state, including
d. injecting a positive current I_{g,op} from the emitter/source to the gate of said module, an initial voltage V_{0,op} of the module, gate-emitter/source, being superior to a flatband voltage V_{fb},
e. measuring the voltage V_{ig,op}(t) across the current source,
f. stop the current injection I_{g,op} when the voltage of the module becomes inferior to the flatband voltage V_{fb},
then,
at least one third series of operations including
g. comparing the voltages V_{ig,ref}(t) and V_{ig,op}(t) measured respectively during one said first series and one said second series,
h. deducing, from the comparison, a temperature dispersion T_{j,dev} across the module.

2. The method according to claim 1, wherein each of said at least one first series and said at least one second series further comprises:
i. acquiring absolute average temperatures T_{av,ref} and T_{av,op} of the module, and wherein said second series is repeatedly executed until that the difference between the absolute average temperatures T_{av,ref} and T_{av,op} acquired during said at least one first series and during said second series is equal or inferior to a predetermined value ΔTₗᵢₘ.

3. The method according to claim 2, wherein a plurality of said first series is executed at different absolute average temperatures T_{av,ref,n},
and wherein said first series are executed during states different from an operational state of the module.

4. The method according to claim 1,
wherein a plurality of said first series is executed at different absolute average temperatures T_{av,ref,n},
wherein each said first series is executed during a reference and operational state of the module, and before reaching a predefined operating age limit in operational operation of said module.

5. The method according to claim 1,
wherein said third series further comprises, before comparison:
g′. adjusting, in time and in offset, the measured voltage V_{ig,op}(t) during said at least one second series with respect to the waveform of the measured voltage V_{ig,ref}(t) during said at least one first series.

6. The method according to claim 5, wherein each said at least one first series is executed when the power transferred by the module is inferior to a predefined limit strictly inferior to the nominal maximum load of the module.

7. A power semiconductor module comprising a single Metal-Oxide-Semiconductor, a single Metal-insulator-Semiconductor or a set of Metal-Oxide-Semiconductors or Metal-insulator-Semiconductors paralleled connected, and being arranged to implement the method according to claim 1.

8. Computer software comprising instructions to implement the method according to claim 1 when the software is executed by a processor.

9. Computer-readable non-transient recording medium on which a software is registered to implement the method according to claim 1 when the software is executed by a processor.
